(19) United States
(12) Patent Application Publication
(10) Pub. No.: US 2008/0224276 A1
(43) Pub. Date: Sep. 18, 2008

(54) Semiconductor device package

(75) Inventors: Wen-Kun Yang, Hsin-Chu City (TW); Diann-Fang Lin, Hukou Township (TW)

Correspondence Address: ABELMAN, FRAYNE & SCHWAB, 666 THIRD AVENUE, 10TH FLOOR, NEW YORK, NY, 10017, US

(73) Assignee: ADVANCED CHIP ENGINEERING TECHNOLOGY

(21) Appl. No.: 11/724,069

(22) Filed: Mar. 13, 2007

(51) Int. Cl. H01L 23/552; H01L 21/58

(52) U.S. Cl. 257/659; 438/108; 257/E23.114; 257/E21.505

(57) ABSTRACT

The present invention provides a package structure and a method for forming the same; wherein the structure comprises a substrate with certain open through holes filled with conducting metals for performing electrical connection or heat dissipation, a chip with bonding pads attached on the contacting pad by an adhesive with high thermal conductivity, wire bounded the contacting pad and the chip pad, a protection layer covered on the chip, wire and a portion of pad by molding or dispensing and a solder ball disposed on the pad. The advantages of the present invention are: the structure is reduced; the heat dissipation of the structure is enhanced; the structure can form package on package structure; the pads provides better ground shielding, heat dissipation of the structure.

### FIELD OF THE INVENTION

The present invention relates to an structure and a method for semiconductor package, and more particularly to thin semiconductor package.

### DESCRIPTION OF THE PRIOR ART

In the field of semiconductor devices, the device density is increased continuously; therefore reducing the device dimension is demanding. Chip package technique is highly influenced by the development of integrated circuits, therefore, as the size of electronics has became demanding, so does the package technique. For the reasons mentioned above, the trend of package technique is toward ball grid array (BGA), flip chip (FC-BGA), chip scale package (CSP), Wafer level package (WLP) today; wherein, the structure formed by WLP has extremely small dimension and good electrical properties. By utilizing WLP technique, the manufacturing cost and time is reduced and the resulting structure of WLP can be equal to the chip; therefore, this technique can meet the demands of miniaturization of electronic devices.

Though the WLP technique has advantages mentioned above, some issues still exist influencing the acceptance of WLP technique. For instance, some technical involves the usage of chip that directly formed on the upper surface of the substrate and the pads of the semiconductor chip will be redistributed through redistribution processes involving a redistribution layer (RDL) into a plurality of metal pads in an area array type. The build up layer also increases the size of the package. Therefore, the thickness of the package is increased, which conflict with the demand of reducing the size of a chip. The chip is folded in the build up layers; therefore the heat dissipation and ground shielding of the structure are another question needs to be solved.

Therefore, the present invention provides a package structure with shrinkage size, better heat dissipation and ground shielding to overcome the aforementioned problem.

### SUMMARY OF THE INVENTION

One advantage of the present invention is providing a substrate with wiring circuit and open through holes filled with metal for connecting pads disposed on opposite side of the substrate.

One advantage of the present invention is providing a thinner structure.

One advantage of the present invention is that the chip is attached on the substrate with an adhesive with higher thermal conductivity.

One advantage of the present invention is utilizing a pick and place machine.

One advantage of the present invention is bonding the chip pads with pads on substrate by wire.

One advantage of the present invention is forming a top protection layer by molding or dispensing.

One advantage of the present invention is placing solder balls on the pads.

One advantage of the present invention is attaching the solder ball on pads by re-flowing.

One advantage of the present invention is providing a metal layer for achieving better thermal dissipation and ground shielding of the structure.

One advantage of the present invention is providing a metal layer able to function as antenna.

One advantage of the present invention is providing a simple manufacturing process.

One advantage of the present invention is providing a package on package (PoP) structure and a stacking process forming the same.

The present invention provides a package structure comprising a substrate with certain open through holes formed therein; wherein said open through holes are filled with conducting metals for performing electrical connection and heat dissipation; a pad disposed on the surface of the substrate; a chip with chip pad attached on the substrate by an adhesive with high thermal conductivity; a wire bonded the pad and chip pad for keeping electrical connection; a solder ball disposed on the pad.

The present invention provides a method for manufacturing a package structure, comprising: providing a substrate (in panel form) with a contact metal pad and certain open through holes filled with a conducting metal; laminating or coating a photo resistor (PR) and performing a exposure and developing process for protecting the solder metal pads area; dispensing an adhesive material on a substrate (with high thermal conductivity); attaching the chip on the substrate; wire bonding the bonding pads of the chip and the contact metal pads of the substrate; forming a top protection layer by molding or dispensing; stripping the PR and cleaning the solder metal pads by plasma clean; printing the flux; placing a solder ball on said pad; reflowing the solder ball.

### BRIEF DESCRIPTION OF THE DRAWINGS

FIG. 1 illustrates a package structure discloses in one embodiment of the present invention.

FIG. 2 illustrates a package structure discloses in another embodiment of the present invention.

FIG. 3 illustrates a stacking package structure discloses in another embodiment of the present invention.

FIG. 4 illustrates a package structure disclosed in FIG. 1 disposed on a PCB mother board.

FIG. 5 illustrates a package structure disclosed in FIG. 3 disposed on a PCB mother board.

### DESCRIPTION OF THE PREFERRED EMBODIMENT

The invention will now be described in greater detail with preferred embodiments of the invention and illustrations attached. Nevertheless, it should be recognized that the preferred embodiments of the invention is only for illustrating. Besides the preferred embodiment mentioned here, present invention can be practiced in a wide range of other embodiments besides those explicitly described, and the scope of the present invention is expressly not limited expect as specified in the accompanying Claims.

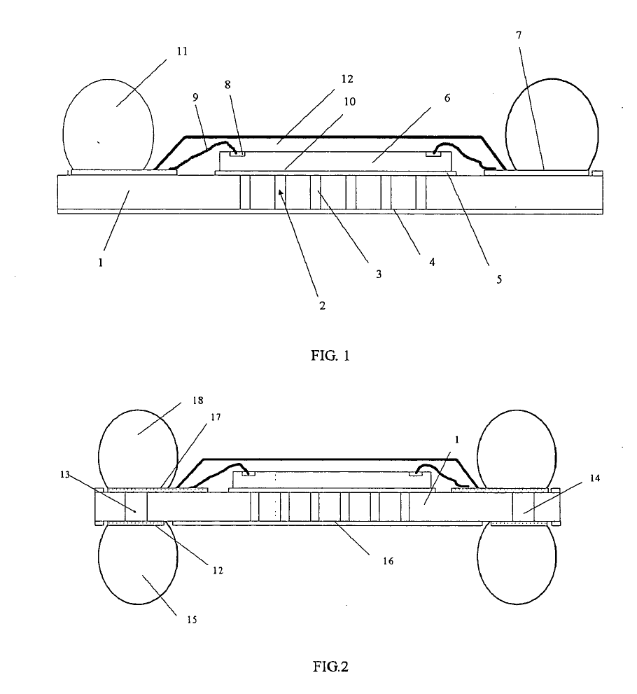

FIG. 1 illustrates a package structure discloses in one embodiment of the present invention. A substrate 1, preferably, made of FR4/FR5/BT or metal/alloy, is provided with several open through holes 2 formed therein; wherein the open through holes 2 filled with conducting material such as metal 3 (preferably copper material). A conductive layer, for instant metal layer 4, is attached on one surface of the substrate 1 and a conductive (metal) layer 5 is formed on another surface of substrate 1; wherein the metal 3 connects the metal layer 4 and metal layer 5 for achieving better heat dissipation and ground shielding. In another embodiment of the present invention, a material for enhancing heat dissipation is coated on the metal layer 4. A solder metal pad 7 forms beside the metal layer 5 with a distance between them.

A chip 6 with a chip pad 8 formed thereon disposed on the metal layer 4 by an adhesive 10; wherein adhesive 10 can provide better thermal conductivity for dissipating heat generated by chip 6. A wire 9 bonds the chip pad 8 and the solder metal pad 7 for keeping electrical connection between them.

A protection layer 12 is applied covering the chip 6, wire 9 and a portion of the solder metal pads 7, wherein the protection layer 12 is resin compound, liquid compound or silicon rubber. A Solder ball 11 is disposed on the solder metal pad 7 for conducting electricity; wherein the height of the solder ball is about 0.2 mm to 0.35 mm depends on the diameter of the solder ball.

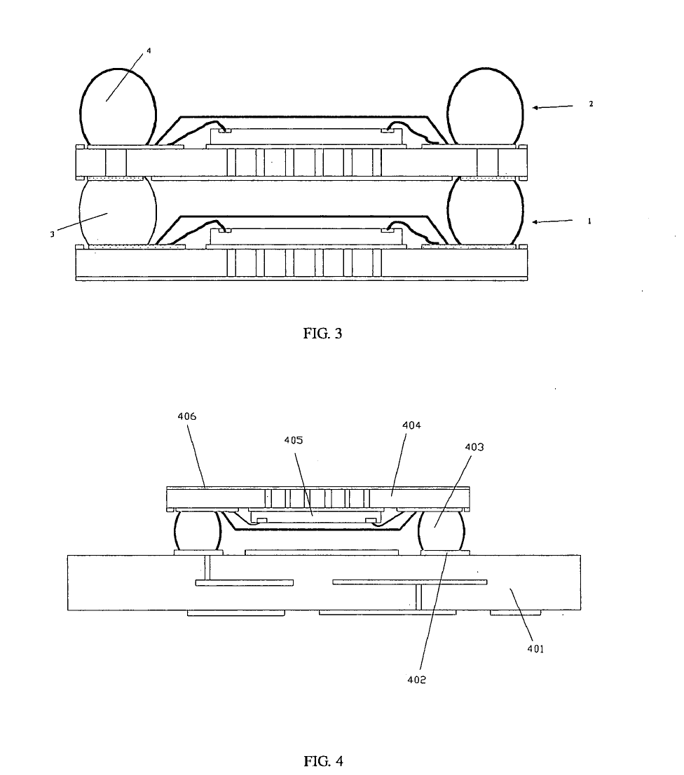

FIG. 2 illustrates a package structure discloses in another embodiment of the present invention. The structure illustrates in FIG. 2 is quite the same as that illustrate in FIG. 1 but the metal layer 4 illustrated in FIG. 2 is divided to solder metal pads 12 and a metal layer 16 as illustrated in FIG. 2; wherein, referring to FIG. 2, an open through hole 13 is formed in the substrate 1 and a conducting material (for example metal or alloy) 14 is filled inside for keeping electrical connection between the solder metal pads 12 and 17. Another solder ball 15 is disposed on the solder metal pad 12 opposite to the solder ball 18.

FIG. 3 illustrates a stacking package structure discloses in another embodiment of the present invention. Referring to the structure illustrated in the FIG. 3, the structure 1 is the same as illustrated in FIG. 1 without solder ball and the structure 2 stacks upon the structure 1 is the same as illustrated in FIG. 2; wherein both ends of the solder ball 3 is stage type for keeping electrical connection between the structure 1 and the structure 2. Another solder ball 4 is erected on the structure 2 for keeping electrical connection with other component, for example memory device; therefore, a structure referred to as PoP structure is formed.

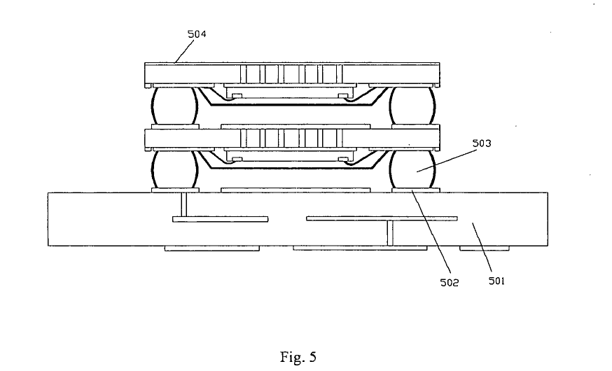

FIG. 4 illustrates a package structure disclosed in FIG. 1 disposed on a PCB mother board. The package structure illustrated in FIG. 1 is disposed on a PCB board 401 with several metal pads 402 formed therein and thereon; wherein the solder ball 403 (stage type) disposed on the metal pad 402 for keeping electrical connection between the chip 405 and PCB board 401; wherein the distance between the top of the PCB board 401 and the surface of the metal layer 406 opposite to the chip 405 is about 300 to 400 μm. Hence, a flip-chip configuration between the substrate 404 and the PCB board 401 is formed; wherein the conductive material of the substrate constructs an EM shielding for said chip 405.

FIG. 5 illustrates a package structure disclosed in FIG. 3 disposed on a PCB mother board. The package structure illustrated in FIG. 3 is disposed on a PCB board 501 with several metal pads 502 formed therein and thereon; wherein the solder ball 503 (stage type) disposed on the structure 2 (as shown in FIG. 3) is erected on the metal pad 502; therefore the PoP structure is disposed on the PCB 1 with upside down configuration. In another embodiment of the present invention, a material for enhancing heat dissipation is coated on the metal layer 504.

The present invention also provides a method for manufacturing a package structure of the present invention. The method provides a substrate (in panel form), preferably, FR4/FR5/BT or metal/alloy, with preformed conducting material for example, metal, comprising a solder metal, a contacting metal pad and a metal layer, and through holes for keeping electrical connection between a chip and a metal layer that would be disposed on the opposite surface of the substrate in the following step. In another embodiment of the present invention, another open through holes with conducting material, for example, metal, filled in and a conducting pad, for example, metal ball pad formed thereon are preformed in the substrate for keeping electrical connection between the conducting metal pads. Next, a photo resistor material is laminated or coated on the substrate (panel form) and then a exposure/developing process is performed to keep the photo resistor covering the solder metal pads area. Subsequently, an adhesive material (with high thermal conductivity) is dispensed on a substrate and then a pick and place machine is used for attaching the chip on one side of the substrate with adhesive; wherein the thickness of the chip is about 20 to 100 μm. The next step is to wire bond the bonding pads of the chip to the conducting metal pads disposed on the substrate. A top protection layer is formed by molding or dispensing; wherein the protection layer is a resin compound, a liquid compound or a silicon rubber. The photo resistor is stripped to open the solder metal pads area and then the pads are cleaned by plasma clean. Next, the solder balls are placed on the solder metal pads, and then followed by re-flowing the solder ball for attaching the solder ball on the solder metal pad. Then, the next step is to singulate the panel to complete a package structure. It is appreciated that the term metal may refer as any conductive material, metal, alloy or conductive compound. In another embodiment of the present invention, the method further comprising stacking another package structure on the package structure to form a PoP structure

Subsequently, the chip and the substrate (package form) are combined by surface mount technology (SMT), followed by attaching the solder balls of the substrate for connecting pads of a PCB, thereby a flip-chip like configuration between the substrate and the PCB I formed; wherein the conductive material of the substrate constructs an EM shielding for the chip. Although preferred embodiments of the present invention have been described, it will be understood by those skilled in the art that the present invention should not be limited to the described preferred embodiments. Rather, various changes and modifications can be made within the spirit and scope of the present invention, as defined by the following Claims.

What is claimed is:

1. A package structure, comprising
a substrate with open through holes formed therein; wherein said open through holes are filled with conducting material for performing electrical connection and heat dissipation;
a contacting pad formed on a surface of said substrate;
a chip with a chip bonding pad attached on said contacting pad by an adhesive with high thermal conductivity;
a wire bonded said contacting metal pad and said chip bonding pad for keeping electrical connection;
a protection layer covering said chip, said wire and a portion of said contacting pad; and
a solder ball disposed on said pad.

2. The structure of claim 1, wherein said protection layer is resin compound, liquid compound or silicon rubber.

3. The structure of claim 1, wherein said conducting material functions as an antenna and ground shielding.

4. The structure of claim 1, wherein said package structure stacks on another said package structure for forming a package on package structure.

5. The structure of claim 1, wherein said substrate is FR4/FR5/BT or metal/alloy.

6. The structure of claim 1, wherein the surface of said pad connected to said conducting metals coated a layer of material for dissipating heat generated from said chip.

7. A method for manufacturing a flip chip package structure, comprising
providing a substrate with a contacting pad and open through holes filled with a conducting material;
laminating a photo resistor to cover the solder metal pads area;
dispensing an adhesive on a contacting pad of said substrate;
attaching said chip on said substrate;
wire bonding said chip and said contacting pad;
forming a top protection layer by molding or dispensing;
stripping the photo resistor to open the solder metal pads area;
placing a solder ball on said solder metal pad;
reflowing said solder ball to complete a package structure;

8. The method of claim 7, further comprising surface mounting said chip and said substrate, followed by attaching said solder balls of said substrate to connecting pads of a PCB, thereby forming a flip-chip like configuration between said substrate and said PCB and wherein said contacting pad of said substrate constructs a EM shielding for said chip.

9. The method of claim 7, further comprising stacking another said package structure on said package structure for forming a PoP structure.

10. The method of claim 7, wherein step for attaching said chip on said substrate is performed by pick and place machine.

11. The method of claim 7, wherein said substrate is FR4/FR5/BT or metal/alloy.

12. The method of claim 7, wherein said protection layer is resin compound, liquid compound or silicon rubber.

13. The method of claim 7, wherein said protection layer covering said chip, said wire and a portion of said pad.

14. The method of claim 7, further comprising coating a layer of material on the surface of said pad connected to said conducting metals for dissipating heat generated from said chip.
